(19) United States
(12) Patent Application Publication
(10) Pub. No.: US 2005/0121064 A1
(43) Pub. Date: Jun. 9, 2005

(54) Cooling and electricity generation apparatus, a portable terminal adopting the same, and a method of operating the portable terminal

(75) Inventor: Jae-Min Seo, Suwon-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., GYEONGGI-DO (KR)

(21) Appl. No.: 10/912,798

(22) Filed: Aug. 6, 2004

(30) Foreign Application Priority Data
Dec. 8, 2003 (KR) 88705/2003

(51) Int. Cl. H01L 35/00

(52) U.S. Cl. 136/200

(57) ABSTRACT

A cooling and electricity generation apparatus, a mobile communication terminal adopting the same, and a method of operating the mobile communication terminal are disclosed. A cooling and electricity generation apparatus has a cooling module including a first thermoelectric semiconductor installed at a predetermined area for removing heat generated at the predetermined area, and an electricity generation module including a second thermoelectric semiconductor having a heat absorbing plate and a heatsink. The heat absorbing plate is installed at a heating part of the first thermoelectric semiconductor of the cooling module so as to generate electromotive force by using a temperature difference between the heat absorbing plate and the heatsink. A portable terminal having the cooling and electricity generation apparatus has a power source unit used as an auxiliary power source of an internal power source by using electromotive force generated from the electricity generation module of the cooling and electricity generation unit. A step of checking a present operation mode and operating the cooling and electricity generation apparatus if the present operation mode is a predetermined operation mode is carried out. A step of closing an operation of the cooling and electricity generation apparatus if the present operation mode is not the predetermined operation mode is carried out.

### PRIORITY

This application claims priority to an application entitled “COOLING AND ELECTRICITY GENERATION APPARATUS, PORTABLE TERMINAL ADOPTING THE SAME, AND METHOD OF OPERATING THE PORTABLE TERMINAL” filed in the Korean Intellectual Property Office on Dec. 8, 2003 and assigned Serial No. 2003-88705, the contents of which are hereby incorporated by reference.

### BACKGROUND OF THE INVENTION

1. Field of the Invention

The present invention relates to a cooling system or an electricity generation system using a thermoelectric transformation, and more particularly to an apparatus capable of simultaneously performing a cooling operation and an electricity generation operation through constructing a cooling system and an electricity generation system using a thermoelectric transformation such that they cooperate with each other, a mobile communication terminal adopting the same, and a method of operating the mobile communication terminal.

2. Description of the Related Art

Most of electrical and electronic products, such as PDAs (personal digital assistant) or mobile communication terminals, generate heat caused by current consumption in each of such pruduct's components when these electrical and electronic products are operated. When such products are used for a long time, each part of the electrical and electronic products may be influenced by a high temperature generated at internal areas of the products. Accordingly, most of electronic products are constructed to include a cooling or a ventilating apparatus in order to remove or ventilate heat generated by the electronic products.

However, in a portable terminal requiring portability and mobility, such as a PDA or a mobile communication terminal, it is a burden for the portable terminal having a compact size to have the ventilating or cooling apparatus in addition to its essential parts. In addition, although such a portable terminal generally uses a battery as a power source, it is necessary for apparatuses using such a battery to reduce consumption of the battery power, making it difficult to provide such ventilating or cooling apparatus in the portable terminal because it may cause additional power consumption.

### SUMMARY OF THE INVENTION

Accordingly, the present invention has been made to solve the above-mentioned problems occurring in the prior art, and an object of the present invention is to provide a cooling and electricity generation apparatus capable of reducing power consumption thereof while carrying out a cooling operation of the cooling and electricity generation apparatus.

Another object of the present invention is to provide a cooling and electricity generation apparatus and a portable terminal adopting the same, that is capable of removing heat generation and achieving electromotive force by using a temperature difference derived from a part in which heat generation is removed.

Still another object of the present invention is to provide a method of operating an internal cooling apparatus while reducing power consumption of a battery installed in a portable terminal adopting a cooling and electricity generation apparatus.

In order to accomplish the above objects, according to one aspect of the present invention, there is provided a cooling and electricity generation apparatus including a cooling module having a first thermoelectric semiconductor installed at a predetermined area for removing heat generated at the predetermined area, and an electricity generation module including a second thermoelectric semiconductor having a heat absorbing plate and a heatsink, wherein the heat absorbing plate is installed at a heating part of the first thermoelectric semiconductor of the cooling module so as to generate an electromotive force by using a temperature difference between the heat absorbing plate and the heatsink.

In order to accomplish the above objects, according to another aspect of the present invention, there is provided a portable terminal having a cooling and electricity generation apparatus, the portable terminal comprising a cooling and electricity generation unit including a cooling module having a first thermoelectric semiconductor installed at a predetermined area of the portable terminal for removing heat generated at the predetermined area of the portable terminal and an electricity generation module having a second thermoelectric semiconductor having a heat absorbing plate and a heatsink, the heat absorbing plate being installed at a heating part of the first thermoelectric semiconductor of the cooling module so as to generate an electromotive force by using a temperature difference between the heat absorbing plate and the heatsink, and a power source unit used as an auxiliary power source of an internal power source by using the electromotive force generated from the electricity generation module of the cooling and electricity generation unit.

In order to accomplish the above objects, according to still another aspect of the present invention, there is provided a method of operating a portable terminal having a cooling and electricity generation apparatus including a cooling module having a first thermoelectric semiconductor for removing heat generated at a predetermined area and an electricity generation module having a second thermoelectric semiconductor for generating electromotive force by using a temperature of a heating part of the first thermoelectric semiconductor of the cooling module, the method including the steps of checking a present operation mode and operating the cooling and electricity generation apparatus if the present operation mode is a predetermined operation mode, and terminating operation of the cooling and electricity generation apparatus if the present operation mode is not the predetermined operation mode.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram showing a mobile communication terminal adopting a cooling and electricity generation apparatus according to one embodiment of the present invention;

FIG. 2 is a block diagram showing details of construction of a cooling and electricity generation unit shown in FIG. 1; and

FIG. 3 is a flowchart showing a cooling and electricity generation procedure of a mobile communication terminal according to one embodiment of the present invention.

### DETAILED DESCRIPTION OF THE PREFERRED EMBODIMENT

Hereinafter, a preferred embodiment according to the present invention will be described with reference to the accompanying drawings. In the following description of the present invention, a detailed description of known functions and configurations incorporated herein will be omitted when it may make the subject matter of the present invention rather unclear.

A cooling and electricity generation apparatus according to the present invention includes an electronic cooling module that absorbs heat on one side and generates heat on another side, while a voltage is being applied to the apparatus. The apparatus also includes a thermoelectric generator capable of generating electricity by using a voltage, that is, a thermoelectromotive force is derived from a temperature difference caused by the electronic cooling module. Hereinafter, a construction and an operation of the cooling and electricity generation apparatus according to the present invention will be explained in detail with reference to a construction and an operation of a mobile communication terminal, for example, a portable terminal adopting such a cooling and electricity generation apparatus.

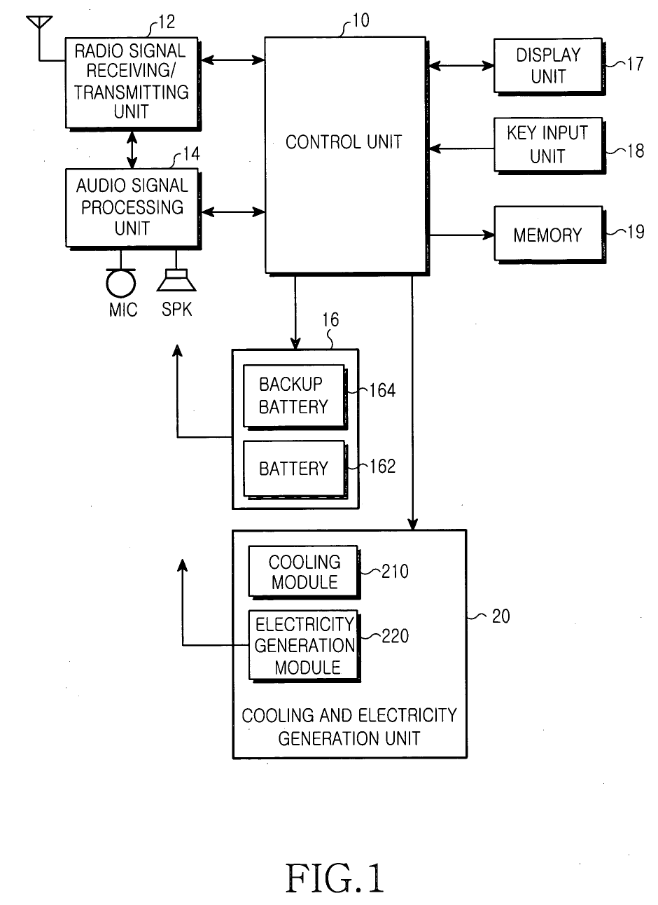

FIG. 1 is a block diagram showing a mobile communication terminal adopting a cooling and electricity generation apparatus according to one embodiment of the present invention. Referring to FIG. 1, according to the construction and operation of the mobile communication terminal adopting the cooling and electricity generation apparatus of the present invention, a control unit 10 carries out a general control operation of the mobile communication terminal. Particularly, it controls an operation of a cooling and electricity generation unit 20 used for removing heat and generating electromotive force according to the present invention.

A radio signal receiving/transmitting unit 12 converts a frequency band of radio channel data received through an antenna to a lower level frequency band, and outputs the radio channel data to the control unit 10 and an audio signal processing unit 14 after classifying frequency bands according to each channel. Data transmitted to the control unit 10 from the radio signal receiving/transmitting unit 12 include first data received through a traffic channel, or a paging signal and a signaling signal received through a control channel. Also, data outputted to the audio signal processing unit 14 becomes audio signal data, which is received when a voice call is set. In addition, the radio signal receiving/transmitting unit 12 outputs through the antenna a radio signal having a proper frequency band, by converting the frequency band to a higher level frequency band in order to transmit the data received from the control unit 10 or the coded audio signal data received from the audio signal processing unit 14.

In general, the audio signal processing unit 14 includes a vocoder. Herein, the audio signal processing unit 14 converts the coded audio signal data received from the radio signal receiving unit 12 to an electric audio signal through decoding the coded audio signal data under the control of the control unit 10, and outputs the converted electric audio signal through a speaker. Also, the speaker outputs the received electric audio signal after converting the received electric audio signal to an audible sound. In addition, the audio signal processing unit 14 outputs the electric audio signal to the radio signal receiving unit 12 after coding the electric audio signal received from a microphone.

A memory 19 includes read only memory (ROM) and random access memory (RAM). The memory 19 is divided into a first storage area used for storing data which is required for an operating program of the control unit 10, a second storage area defined by a user, and a third storage area used for temporarily storing data generated according to various operations of the control unit 10.

A display unit 17 includes a device for displaying an operational status of the mobile communication terminal, such as an LCD (Liquid Crystal Display), by using characters or icons, a vibration motor, and an alarm lamp. The LCD of the display unit 17 displays a present status of the mobile communication terminal, and displays data inputted by a key operation of a user through converting the data to the character or the icon. In general, a key inputting unit 18 has a key matrix structure and includes numerical keys for dialing and functional keys for operating various functions of the mobile communications terminal.

A power source unit 16 may include a battery 162 and a backup battery 164. The power source 16 provides an operational power to various functional units of the mobile communication terminal. The cooling and electricity generation unit 20 includes a cooling module 210 installed at a predetermined area or portion of an internal circuit of the mobile communication terminal, that is, a portion making a contact with the battery 162 according to one embodiment of the present invention. The predetermined portion or area generating more heat than other portions or areas of the internal circuit. This it done in order to remove heat generated in the predetermined area and is performed under the control of the control unit 10. The cooling and electricity generation unit 20 further includes an electricity generation module 220 used for generating an electromotive force by using a temperature difference caused when the cooling module 210 removes heat from the predetermined area. Hereinafter, the construction and operation of such a cooling and electricity generation unit 20 will be explained in detail with reference to the accompanying drawings.

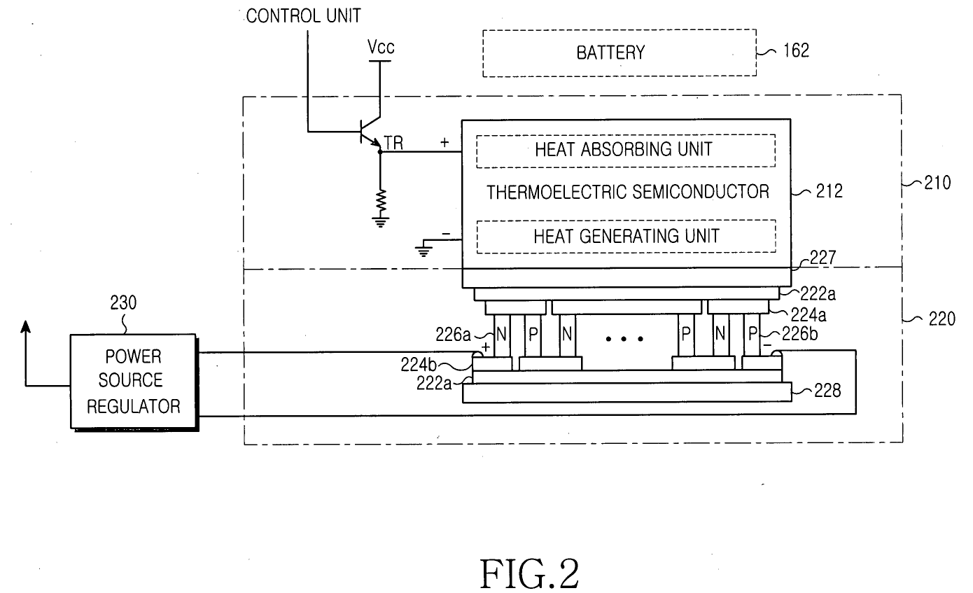

FIG. 2 is a block diagram showing details of the construction of the cooling and electricity generation unit shown in FIG. 1. Referring to FIG. 2, the cooling module 210 of the cooling and electricity generation unit 20 according to the present invention includes a thermoelectric semiconductor 212 for cooling the battery 162 through absorbing heat generated from the battery 162. The thermoelectric semiconductor 212 is constructed to have a Peltier effect in which heat is absorbed into the thermoelectric semiconductor 212 if current is applied to the thermoelectric semiconductor 212 including two mutually different semiconductors connected to each other. The thermoelectric semiconductor 212 includes a serial circuit type p-n thermocouple realized by connecting a p-type device and an n-type device to a metal electrode. When current flows from the n-type device to the p-type device such that poles of both branch terminals of p-n thermocouple have a positive pole (+) and a negative pole (−), respectively, holes in the p-type device are shifted towards the negative pole, and electrons in the n-type device are shifted towards the positive pole. At this time, the holes and the electrons absorb heat from a p-n junction electrode formed at an upper portion thereof and move towards both branch terminals formed at a lower portion thereof, so the upper p-n junction portion is cooled, thereby absorbing heat from a peripheral area thereof and the lower branch terminals emit heat.

In regard to the thermoelectric semiconductor 212, a heat absorbing unit is located adjacent to a predetermined area of the battery 162 generating considerable heat in order to remove heat generated by the battery 162. Also, the thermoelectric semiconductor 212 is operated when DC power is applied thereto according to a control signal of the control unit 10.

Meanwhile, the electricity generation module 220 generates the electromotive force through using heat generated from a heat generating unit. The electricity generation module 220 includes a thermoelectric semiconductor representing a Seeback effect in which the electromotive force is generated by creating a temperature difference at a junction part between two mutually different semiconductors. Similar to the thermoelectric semiconductor of the cooling module 210, the thermoelectric semiconductor of the electricity generation module 220 includes a semiconductor thermocouple including a p-type device and an n-type device connected to a metal. Herein, if heat is applied to an upper junction part so that a temperature difference is generated between the upper junction part and a lower junction part, a thermal energy is applied to electrons in the n-type device and holes in the p-type, so the electrons and the holes move towards a low temperature portion because total energy of the electrons and holes is increased. Accordingly, the low temperature portion of the n-type device is electrified with a negative electric charge by the electrons, and the high temperature portion of the n-type device is electrified with a positive electric charge. Also, the p-type device is electrified in a manner opposite to that of the n-type device. An electricity generation operation is carried out by using such potential difference.

Hereinafter, the construction of the electricity generation module 220 will be explained in more detail. The electricity generation module 220 includes a heating absorbing plate 227 attached to the heat generating unit of the thermoelectric semiconductor 212 of the cooling module 210 in order to absorb heat generated from the thermoelectric semiconductor 212, the thermoelectric semiconductor including ceramic substrates 222a and 222b, electric conductors 224a and 224b, and p-n type thermoelectric devices 226a and 226b, which are formed at a lower portion of the heat absorbing plate 227, and a heatsink 228 formed at a lower portion of the thermoelectric semiconductor in order to emit heat.

DC electric power generated from the electricity generation module 220 is applied to a power source regulator 230 such that DC electric power is properly regulated. Then, DC electric power is applied to the backup battery 164 (FIG. 1) or the battery 162 of the power source unit 16 (FIG. 1) in order to charge the backup battery 164 or the battery 162. As a result, battery power required for deriving the cooling and electricity generation unit 20 of the present invention can be supplemented so that power consumption of the battery may be reduced. At this time, it is also possible to supplement power supplied to the cooling and electricity generation unit 20 by using the power generated by the electricity generation module 220.

The mobile communication terminal including the cooling and electricity generation unit 20 having the above described construction and carrying out the above-mentioned operation, operates the cooling and electricity generation unit 20 so that the cooling module 210 of the cooling and electricity generation unit 20 absorbs heat from an internal part of the mobile communication terminal generating relatively more heat (for example, a main substrate or a battery part), thereby cooling the internal part of the mobile communication terminal. At the same time, the electricity generation module 220 may generate electromotive force by using heat generated by the cooling module 210.

Meanwhile, the mobile communication terminal checks an operation mode thereof. If a present operation mode of the mobile communication terminal is a sleep mode, heat is rarely generated from the mobile communication terminal in the sleep mode because operations of internal functional components of the mobile communication terminal are simplified during that mode. Therefore, it is preferred to stop an operation of the cooling and electricity generation unit 20 while the mobile communication terminal is in the sleep mode. In addition, if the present operation mode of the mobile communication terminal is a transmitting mode or a receiving mode, the cooling and electricity generation unit 20 may be operated. Particularly, if the present operation mode of the mobile communication terminal is the transmitting mode, the cooling and electricity generation unit 20 must be operated because a great amount of heat is generated from the mobile communication terminal in that mode.

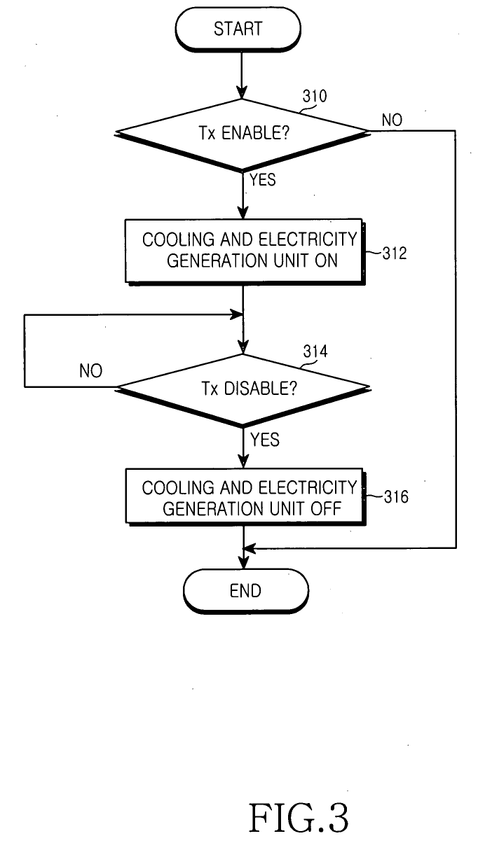

FIG. 3 is a flowchart showing a cooling and electricity generation procedure of a mobile communication terminal according to one embodiment of the present invention. Hereinafter, an operation for controlling the cooling and electricity generation unit 20 of the mobile communication terminal will be explained with reference to FIG. 3. First, in step 310 a control unit 10 of the mobile communication terminal determines whether or not a transmitting terminal of the mobile communication terminal is in an enable state. If the transmitting terminal is in the enable state, step 312 is carried out. In step 312, the control unit 10 transmits an ON signal to the cooling and electricity generation unit 20 in order to drive the cooling and electricity generation unit 20. After that, in step 314 the control unit 10 checks whether the transmitting terminal of the mobile communication terminal is in a disable state. If the transmitting terminal is in the disable state, step 316 is carried out. In step 316, the control unit 10 transmits an OFF signal to the cooling and electricity generation unit 20, thereby stopping the operation of the cooling and electricity generation unit 20.

As mentioned above, the cooling and electricity generation unit according to the present invention can perform a cool operation for equipment, such as a communication terminal, equipped with the cooling and electricity generation unit, while reducing power consumption. At this time, heat generated from equipment can be removed and electromotive force can be obtained through using a temperature difference created in an area in which heat is removed.

As described above, a construction and an operation of a cooling and electricity generation unit and a portable terminal adopting the cooling and electricity generation unit according to one embodiment of the present invention can be achieved. Meanwhile, although a concrete embodiment is explained in the detailed description of the present invention, various modifications are possible within the scope of the present invention. For example, although the cooling and electricity generation unit according to the present invention described above is adopted to the mobile communication terminal, the cooling and electricity generation unit of the present invention is also adopted to portable terminals, such as PDAs or notebook computers, or general electric/electronic appliances for removing heat generated from the above appliances. Accordingly, the scope of the present invention is not defined by embodiments described above, but be defined by the appended claims.

1. A cooling and electricity generation apparatus comprising:
a cooling module including a first thermoelectric semiconductor installed at a predetermined area for removing heat generated at the predetermined area; and
an electricity generation module including a second thermoelectric semiconductor having a heat absorbing plate and a heatsink, wherein the heat absorbing plate is installed at a heating part of the first thermoelectric semiconductor of the cooling module so as to generate an electromotive force by using a temperature difference between the heat absorbing plate and the heatsink.

2. A portable terminal having a cooling and electricity generation apparatus, the portable terminal comprising:
a cooling and electricity generation unit including a cooling module having a first thermoelectric semiconductor installed at a predetermined area of the portable terminal for removing heat generated at the predetermined area of the portable terminal and an electricity generation module having a second thermoelectric semiconductor having a heat absorbing plate and a heatsink, the heat absorbing plate being installed at a heating part of the first thermoelectric semiconductor of the cooling module so as to generate an electromotive force by using a temperature difference between the heat absorbing plate and the heatsink; and
a power source unit used as an auxiliary power source of an internal power source by using the electromotive force generated from the electricity generation module of the cooling and electricity generation unit.

3. A method of operating a portable terminal having a cooling and electricity generation apparatus including a cooling module having a first thermoelectric semiconductor for removing heat generated from a predetermined area and an electricity generation module having a second thermoelectric semiconductor for generating an electromotive force by using a temperature of a heating part of the first thermoelectric semiconductor of the cooling module, the method comprising the steps of:
determining a present operation mode, and operating the cooling and electricity generation apparatus if the present operation mode is a predetermined operation mode; and
terminating operation of the cooling and electricity generation apparatus if the present operation mode is not the predetermined operation mode.
